(19) United States
(12) Patent Application Publication
(10) Pub. No.: US 2004/0124512 A1
(43) Pub. Date: Jul. 1, 2004

(54) Thermal enhance MCM package

(75) Inventors: Su Tao, Kaohsiung (TW); Chian-Chi Lin, Tainan (TW); Chih-Huang Chang, Yungkang City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/693,976

(22) Filed: Oct. 28, 2003

(30) Foreign Application Priority Data
Dec. 30, 2002 (TW) 091137929

(51) Int. Cl. H01L 23/02

(52) U.S. Cl. 257/678

(57) ABSTRACT

A thermal enhance MCM package mainly comprises a first chip, a second chip, a substrate and a thermally conductive device. The first chip and the second chip are electrically connected to the substrate, and the thermally conductive device is mounted on the substrate. The thermally conductive device is exposed to the outside so as to prevent the heat generated from the first chip and the second chip from being accumulated in the substrate and transmitted to the motherboard. Accordingly, the thermal performance of the MCM package will be upgraded.

### BACKGROUND OF THE INVENTION

1. Field of Invention

This invention relates to a semiconductor package. More particularly, the present invention is related to a thermal enhance MCM (multi-chips-module) package for lowering the heat transmitting to the motherboard.

2. Related Art

Integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips-module) package is commonly used in said assembly package and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Originally, the well-know types of MCM packages comprise a side-by-side type and a stacked type. Therein, the MCM package with the side-by-side type is formed by disposing at least two chips on the same surface of a substrate in a parallel manner. Each of said chips is electrically connected to the substrate by wire-bonding and flip-chip bonding. However, the MCM package with the stacked type, for example the multi-chips stacked type, is formed by stacking a first chip upon a second chip, disposing the second chip on a substrate, and then the chips are electrically connected to the substrate by conductive wires and conductive bumps.

When said MCM package comprises a chip with high-density and high frequency integrated circuits formed therein, a lot of heat will be produced from the chip and transmitted to the substrate. However, the substrate is covered by a solder mask layer for protecting internal circuits of the substrate so as to lower the capability of heat dissipation through the air and easily to cause most of the heat to transmit to the motherboard for carrying said MCM package. Accordingly, the other electronic devices mounted on the motherboard will be destroyed or damaged by the excess heat transmitted from the MCM package.

Therefore, providing another thermal enhance MCM package to solve the mentioned-above disadvantages is the most important task in this invention.

### SUMMARY OF THE INVENTION

In view of the above-mentioned problems, an objective of this invention is to provide a thermal enhance MCM package so as to lower the heat transmitting to the motherboard.

To achieve the above-mentioned objective, a thermal enhance MCM package is provided, wherein the thermal enhance MCM package mainly comprises a first chip, a second chip, a substrate and a thermally conductive device. The first chip and the second chip are bonded to the substrate via bumps in a flip-chip manner or electrically connected to the substrate via conductive wires in a wire-bonding manner. And the thermally conductive device, for example a heat spreader, is connected to the first chip and the second chip simultaneously. The heat generated from the first chip and the second chip is transmitted from the thermally conductive device to the substrate by direct contact between the substrate and the thermally conductive device, and the performance of the heat transmission from the thermally conductive device to the outside is better than the performance of the heat transmission from the substrate to the outside so that the heat is partially transmitted to the outside through the thermally conductive device. Accordingly, the heat is not easy to be accumulated in the substrate and not easy to be transmitted to the motherboard, so that the electronic devices mounted on the motherboard will not be easily damaged and the performance of the electronic devices formed on the motherboard will not be lowered.

### BRIEF DESCRIPTION OF THE DRAWINGS

The invention will become more fully understood from the detailed description given herein below illustrations only, and thus are not limitative of the present invention, and wherein:

FIG. 1A is a cross-sectional view of a thermal enhance MCM package according to the first embodiment of the present invention;

FIG. 1B is a top view of a substrate according to the first embodiment of FIG. 1A;

FIG. 2 is a cross-sectional view of a thermal enhance MCM package according to the second embodiment of the present invention;

FIG. 3 is a cross-sectional view of a thermal enhance MCM package according to the third embodiment of the present invention;

FIG. 4 is a cross-sectional view of a thermal enhance MCM package according to the fourth embodiment of the present invention; and

FIG. 5 is a cross-sectional view of a thermal enhance MCM package according to the fifth embodiment of the present invention.

### DETAILED DESCRIPTION OF THE INVENTION

The thermal enhance MCM package according to the preferred embodiment of this invention will be described herein below with reference to the accompanying drawings, wherein the same reference numbers refer to the same elements.

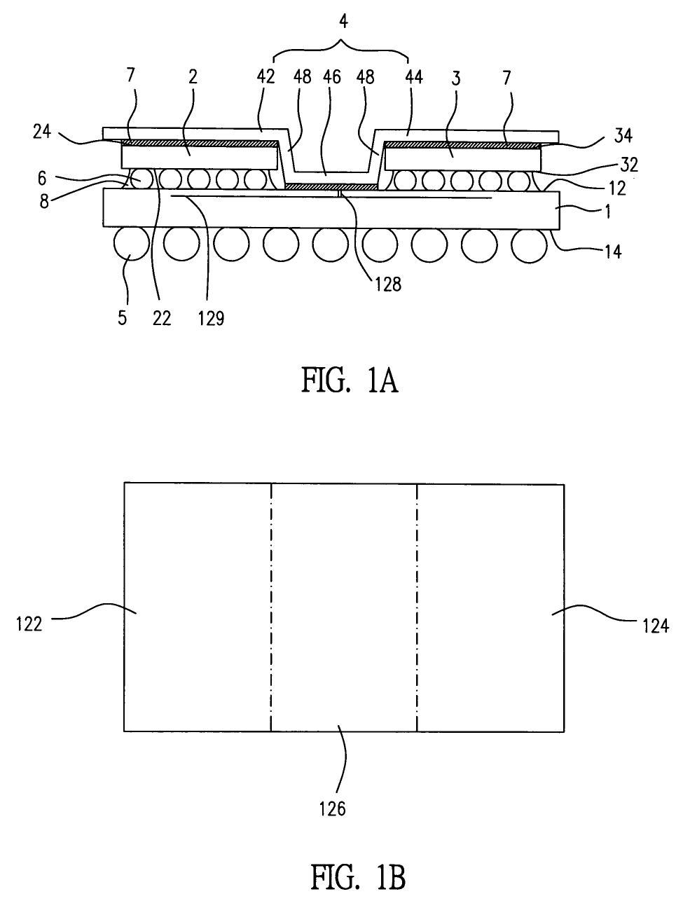

In accordance with a first preferred embodiment as shown in FIG. 1A and FIG. 1B, there is provided a thermal enhance MCM package. The thermal enhance MCM package mainly comprises a substrate 1, a first chip 2, a second chip 3 and a thermally conductive device 4. The substrate 1 has an upper surface 12 and a lower surface 14 opposed to the upper surface 12. The upper surface 12 has a first mounting area 122, a second mounting area 124 and a contacting area 126 for carrying said thermally conductive device 4, and the lower surface 14 has a plurality of solder balls 5 formed thereon and electrically connected to a motherboard (not shown). The first chip 2 and the second chip 3 are disposed on the first mounting area 122 and the second mounting area 124 respectively in a flip-chip manner so that the first chip 2 and the second chip 4 are electrically connected to the substrate 2 through a plurality of bumps 6. In addition, the thermally conductive device 4 has a first chip connecting portion 42, a second chip connecting portion 44, a substrate connecting portion 46 and a joint portion 48 connecting the first chip connecting portion 42, the second chip connecting portion 44 and the substrate connecting portion 46. Therein the first chip connecting portion 42, the second chip connecting portion 44 and the substrate connecting portion 46 are respectively connected to a first back surface 24 of the first chip 2, a second back surface 34 of the second chip 3 and the contacting area 126 through a thermally conductive adhesive 7.

Besides, the contacting area 126 has a plurality of via 128 formed thereon, for example a through hole and a blind hole. Therein the via 128 is filled with a thermally conductive adhesive 7 so as to connect to the circuits layers 129. Thus the heat can be transmitted from the substrate connecting portion 46 of the thermally conductive device 4 to the outside. Moreover there is an electrically conductive layer, for example a nickel layer and a copper layer, formed on the inner wall of the via 128 so that the heat can be transmitted to the outside through the substrate connecting portion 46 of the thermally conductive device 4 and provides a better electrical shielding.

In addition, there is an underfill 8 provided between the first active surface 22 of the first chip 2 and the upper surface 12 of the substrate 1, and between the second active surface 32 of the second chip 3 and the upper surface 12 of the substrate 1 so as to lower the thermal stress due to CTE mismatch between the substrate 1, the first chip 2 and the second chip 3. Besides, the first chip 2, the second chip 3 and the thermally conductive device 4 can be encapsulated by an encapsulation (not shown) exposing the substrate connecting portion 46. Therefore a better thermal dissipation path is provided to prevent the heat from transmitting to the motherboard.

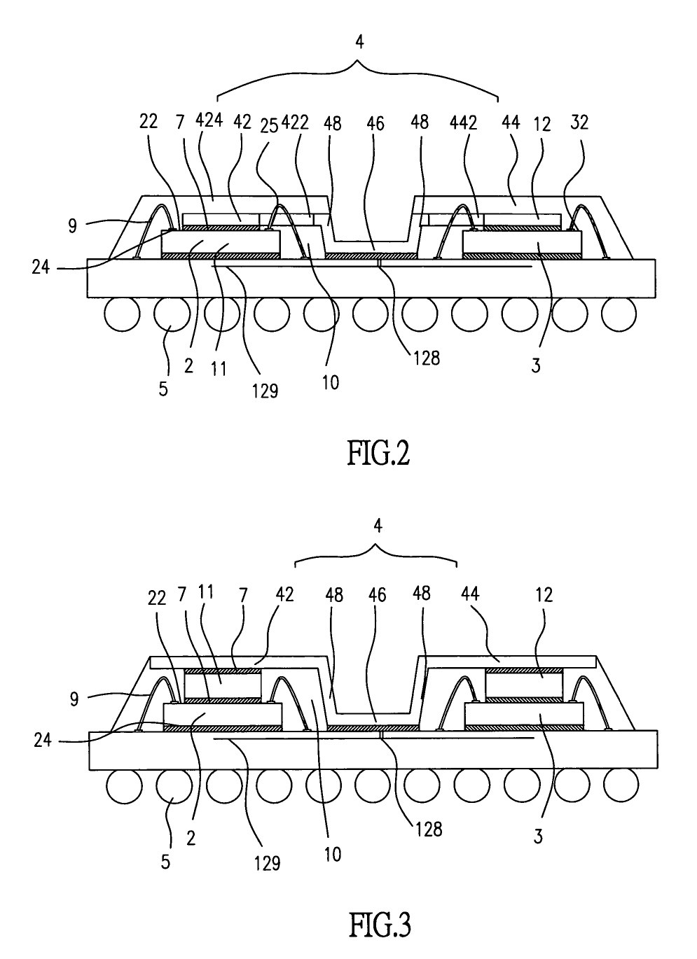

Next, referring to FIG. 2, a second embodiment is provided. The difference of the second embodiment from the first embodiment is that the first chip connecting portion 42 of the thermally conductive device 4 has a plurality of first openings 422 exposing first bonding pads 25 formed on the first active surface 22 of the first chip 2, and the second chip connecting portion 44 of the thermally conductive device 4 has a plurality of second openings 442 exposing second bonding pads 35 formed on the second active surface 32 of the first chip 3. Therein the first chip 2 and the second chip 3 are disposed on the first mounting area 122 and the second mounting area 124 respectively, and electrically connected to the substrate 1 via the conductive wires 9 passing through the first openings 422 and the second openings 442 so that the conductive wires 9 connects the first bonding pads 25 and the first mounting area 122, and connects the second bonding pads 35 and the second mounting area 142.

Moreover, there is an encapsulation 10 formed to encapsulate the substrate 1, the first chip 2, the second chip 3, the conductive wires 9, the first chip connecting portion 42 and the second chip connecting portion 44. However, the encapsulation exposes the substrate connecting portion 46 of the thermally conductive device 4 so as to upgrade the thermal performance of said package.

Next, referring to FIG. 3, there is provided a third embodiment of this invention. When the first chip 2 and the second chip 3 are disposed on the substrate 1 and electrically connected to the substrate 1 by wire-bonding, there are further provided a first dummy chip 11 and a second dummy chip 12 formed on the first chip 1 and the second chip 3 respectively. Therein the first dummy chip 11 further connects to the first chip connecting portion 42, and the second dummy chip 12 further connects to the second chip connecting portion 44. The encapsulation 10 also encapsulates the first dummy chip 11 and the second dummy chip 12. And the thermally conductive device 4 exposes to the outside so as to improve the thermal performance of said package.

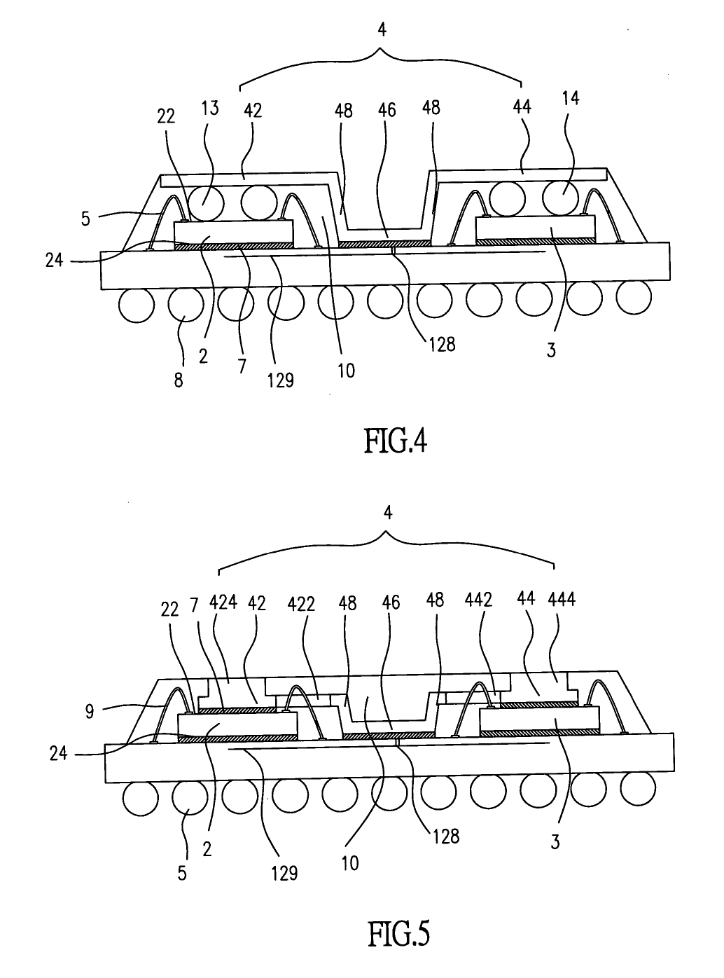

Besides, please pay attention to FIG. 4 showing the fourth embodiment of this invention. The difference of the fourth embodiment from the third embodiment is that the first dummy chip 11 and the second dummy chip 12 are replaced by first thermally conductive bumps 13 and second thermally conductive bumps 14. Namely, the first thermally conductive bumps 13 connects the first chip 2 and the first connecting portion 42, and the second thermally conductive bumps 14 connects the second chip 3 and the second connecting portion 44.

Finally, please refer to FIG. 5 specifying the fifth embodiment of this invention. As shown in the third embodiment and the fifth embodiment, the difference of the fifth embodiment from the third embodiment is that the first chip connecting portion 42 further has a first protrusion 424 and the second chip connecting portion 44 has a second protrusion 444. Therein the first protrusion 424 and the second protrusion 444 are encapsulated in the encapsulation 10 and exposed to the outside so as to provide a better thermal performance of the package. It also should be noted that the reference numeral of each element in FIGS. 2, 3, 4 and 5 corresponds to the same reference numeral of each element in FIG. 1.

Although the invention has been described in considerable detail with reference to certain preferred embodiments, it will be appreciated and understood that various changes and modifications may be made without departing from the spirit and scope of the invention as defined in the appended claims.

What is claimed is:

1. A thermal enhance MCM package, comprising:
a first chip having a first active surface and a first bonding pad formed on the first active surface;
a second chip having a second active surface and a second bonding pad formed on the second active surface;
a substrate having an upper surface with a first mounting area, a second mounting area and a contacting area, wherein the first chip and the second chip are disposed on the first mounting area and the second mounting area respectively and are electrically connected to the substrate; and
a thermally conductive device disposed on the contacting area and covering the first chip and the second chip.

2. The thermal enhance MCM package of claim 1, wherein the thermally conductive device comprises a first chip connecting portion connecting the first chip, a second chip connecting portion connecting the second chip, a substrate connecting portion connecting the substrate, and a joint portion connecting the substrate connecting portion, the first chip connecting portion and the second chip connecting portion with each other, and the substrate connecting portion is attached to the contacting area.

3. The thermal enhance MCM package of claim 1, further comprising a thermally conductive adhesive attaching the thermally conductive device to the substrate.

4. The thermal enhance MCM package of claim 1, wherein the substrate further comprises a circuits layer and a via formed on the contacting area, and the via is filled with a thermally conductive adhesive and connected to the circuits layer.

5. The thermal enhance MCM package of claim 1, wherein the substrate further comprises a grounding layer, a via formed on the contacting area, and an electrically conductive layer is formed on an inner wall of the via and electrically connected to the grounding layer.

6. The thermal enhance MCM package of claim 5, wherein the electrically conductive layer is a copper layer.

7. The thermal enhance MCM package of claim 1, wherein the first chip and the second chip are bonded and electrically connected to the substrate via bumps.

8. The thermal enhance MCM package of claim 7, further comprising an underfill disposed between the first chip and the substrate.

9. The thermal enhance MCM package of claim 7, further comprising an underfill disposed between the second chip and the substrate.

10. The thermal enhance MCM package of claim 1, wherein the thermally conductive device is a heat spreader.

11. The thermal enhance MCM package of claim 1, wherein a material of the thermally conductive device comprises copper.

12. The thermal enhance MCM package of claim 1, further comprising a plurality of solder balls formed on a lower surface of the substrate.

13. The thermal enhance MCM package of claim 2, wherein the first chip connecting portion has a first opening exposing one of the first bonding pads and the second chip connecting portion has a second opening exposing one of the second bonding pads.

14. The thermal enhance MCM package of claim 13, further comprising electrically conductive wires connecting the first bonding pad and the substrate, and connecting the second bonding pad and the substrate.

15. The thermal enhance MCM package of claim 14, wherein the conductive wires pass through the first opening and the second opening.

16. The thermal enhance MCM package of claim 15, further comprising an encapsulation encapsulating the first chip, the second chip, the substrate, the electrically conductive wires, the first chip connecting portion and the second chip connecting portion.

17. The thermal enhance MCM package of claim 16, wherein the encapsulation exposes the substrate connecting portion.

18. The thermal enhance MCM package of claim 16, wherein the encapsulation exposes the joint portion.

19. The thermal enhance MCM package of claim 16, wherein the first chip connecting portion further has a first protrusion and the encapsulation exposes the first protrusion.

20. The thermal enhance MCM package of claim 16, wherein the second chip connecting portion further has a second protrusion and the encapsulation exposes the second protrusion.

21. The thermal enhance MCM package of claim 16, further comprising a first dummy chip connecting the first chip and the first chip connecting portion, and a second dummy chip connecting the second chip and the second chip connecting portion.

22. The thermal enhance MCM package of claim 16, further comprising a first thermally conductive bump connecting the first chip and the first chip connecting portion, and a second thermally conductive bump connecting the second chip and the second chip connecting portion.

23. The thermal enhance MCM package of claim 21, wherein the first chip and the first dummy chip are connecting with each other via a thermally conductive adhesive.

24. The thermal enhance MCM package of claim 21, wherein the second chip and the second dummy chip are connecting with each other via a thermally conductive adhesive.
